(19) United States
(12) Patent Application Publication
(10) Pub. No.: US 2023/0378117 A1
(43) Pub. Date: Nov. 23, 2023

(54) SEMICONDUCTOR APPARATUS AND METHOD FOR MANUFACTURING SEMICONDUCTOR APPARATUS

(71) Applicant: ROHM CO., LTD., Kyoto-shi (JP)

(72) Inventor: Hiromasa KONO, Kyoto-shi (JP)

(21) Appl. No.: 18/363,367

(22) Filed: Aug. 1, 2023

Related U.S. Application Data
(63) Continuation of application No. PCT/JP2022/006325, filed on Feb. 17, 2022.

(30) Foreign Application Priority Data
Mar. 15, 2021 (JP) 2021-041546

(51) Int. Cl. H01L 23/00; H01L 23/495

(52) U.S. Cl. CPC H01L 24/32; H01L 23/49513; H01L 24/29; H01L 24/40; H01L 24/48; H01L 24/73; H01L 24/83; H01L 2224/32245; H01L 2224/29015; H01L 2224/29139; H01L 2224/40175; H01L 2224/48175; H01L 2224/73221; H01L 2224/73263; H01L 2224/73265; H01L 2224/83801

(57) ABSTRACT

A semiconductor device includes a semiconductor element and a conductive bond bonding the semiconductor element to a support. The semiconductor element has first to fourth sides, and the bond has first to fourth edges. Distance between the first side and the first edge in first direction is greater at ends than at the center of the first side in second direction crossing first direction. Distance between the second side and the second edge in first direction is greater at ends than at the center of the second side in second direction. Distance between the third side and the third edge in second direction is greater at ends than at the center of the third side in first direction. Distance between the fourth side and the fourth edge in second direction is greater at ends than at the center of the fourth side in first direction.

### TECHNICAL FIELD

The present disclosure relates to a semiconductor device and a method for manufacturing a semiconductor device.

### BACKGROUND ART

Conventionally, various configurations have been proposed for semiconductor devices with semiconductor elements. JP-A-2018-113359 discloses an example of a conventional semiconductor device. The semiconductor device disclosed in the document includes a lead, a semiconductor element and a conductive bonding material. The semiconductor element is rectangular as viewed in the thickness direction of the semiconductor element. The semiconductor element is disposed on the lead. The conductive bonding material conductively bonds the lead and the semiconductor element to each other.

In the above semiconductor device, to bond the semiconductor element to the lead, for example, the conductive bonding material is heated to be bonded to the lead and the semiconductor element, whereby the lead and the conductive bonding material are placed in a high temperature state. When these are cooled thereafter, thermal stress is produced in the conductive bonding material due to the difference in coefficient of linear expansion between the lead and the conductive bonding material. The thermal stress is relatively large near the outer edge of the semiconductor element as viewed in the thickness direction of the semiconductor element. In particular, the thermal stress tends to concentrate on the periphery of the conductive bonding material near the corners of the semiconductor element. Such a large thermal stress at the periphery of the conductive bonding material may result in defects such as a crack in the periphery or separation of the conductive bonding material from the periphery.

### BRIEF DESCRIPTION OF THE DRAWINGS

FIG. 1 is a perspective view of a semiconductor device according to a first embodiment of the present disclosure.

FIG. 2 is a perspective view of the semiconductor device (seen through a sealing resin) according to the first embodiment of the present disclosure.

FIG. 3 is a plan view of the semiconductor device (seen through a sealing resin) according to the first embodiment of the present disclosure.

FIG. 4 is a sectional view taken along line IV-IV in FIG. 3.

FIG. 5 is a sectional view taken along line V-V in FIG. 3.

FIG. 6 is a sectional view taken along line VI-VI in FIG. 3.

FIG. 7 is a partially enlarged view of FIG. 3.

FIG. 8 is a sectional view taken along line VIII-VIII in

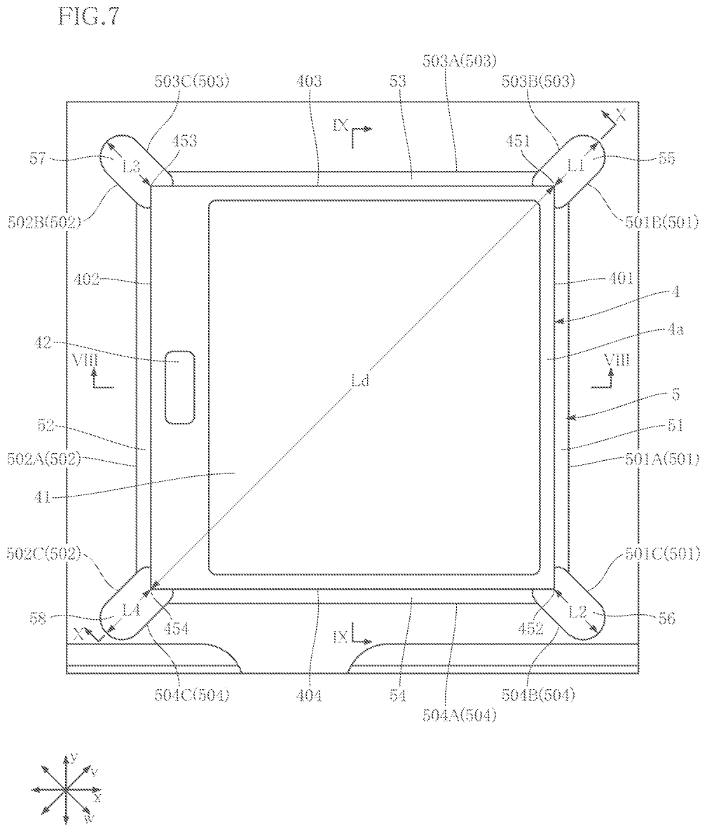

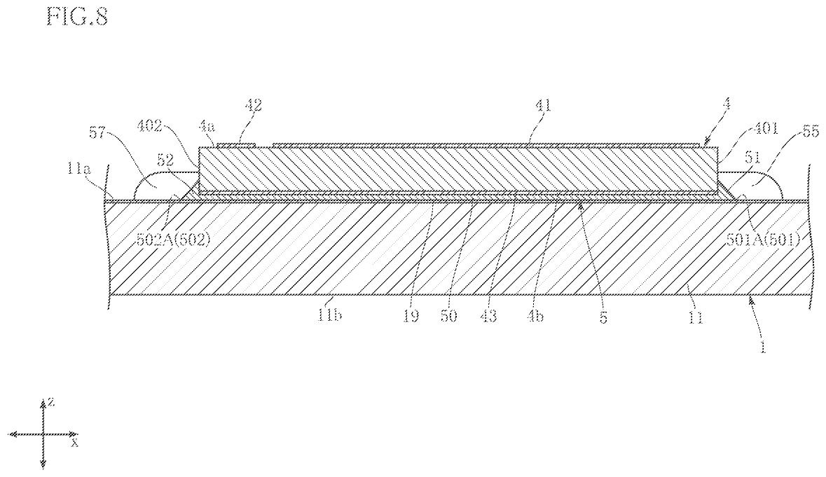

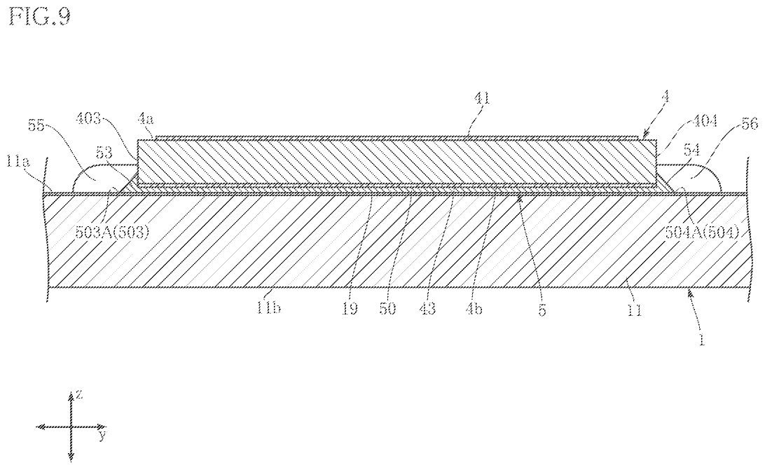

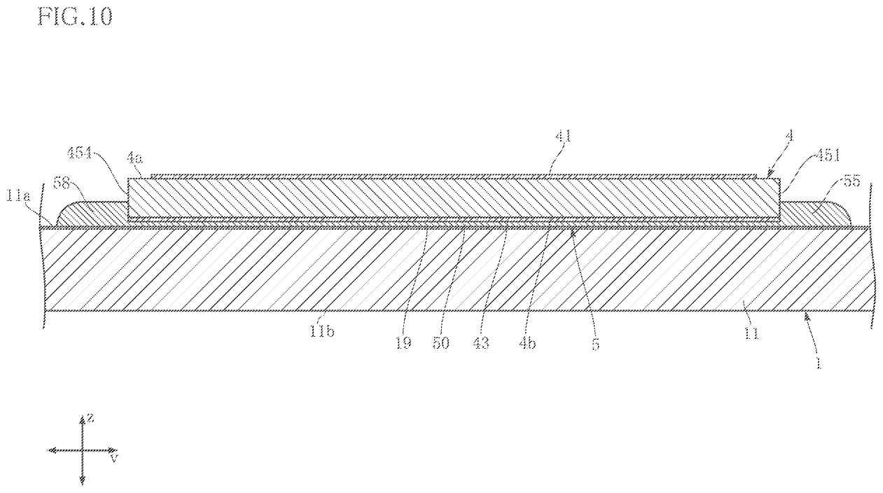

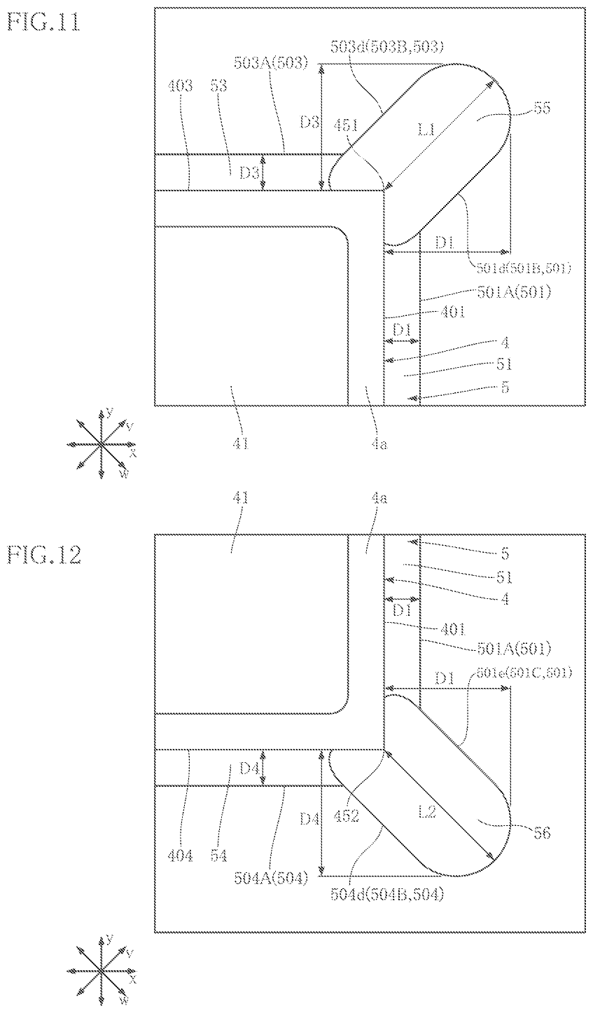

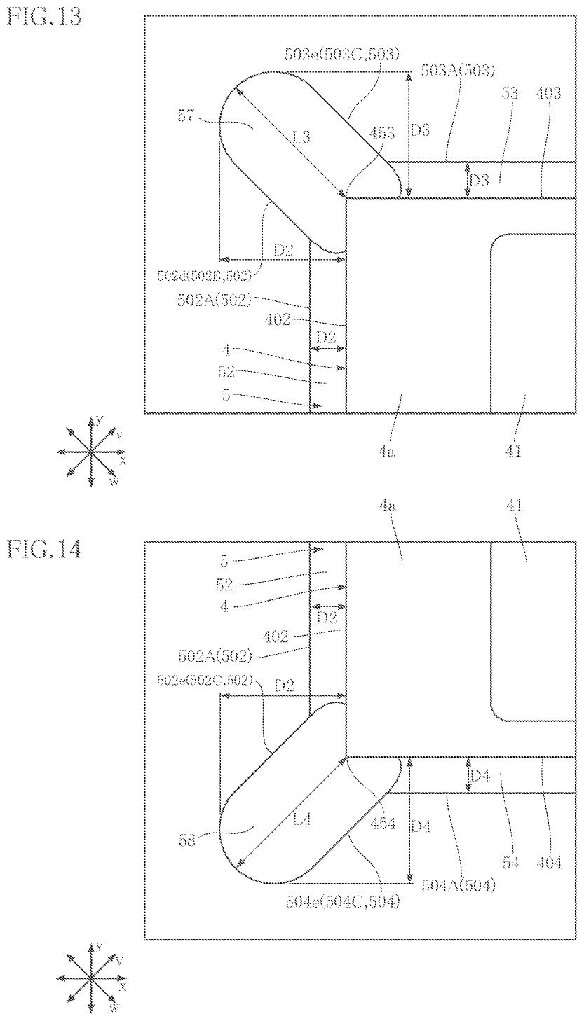

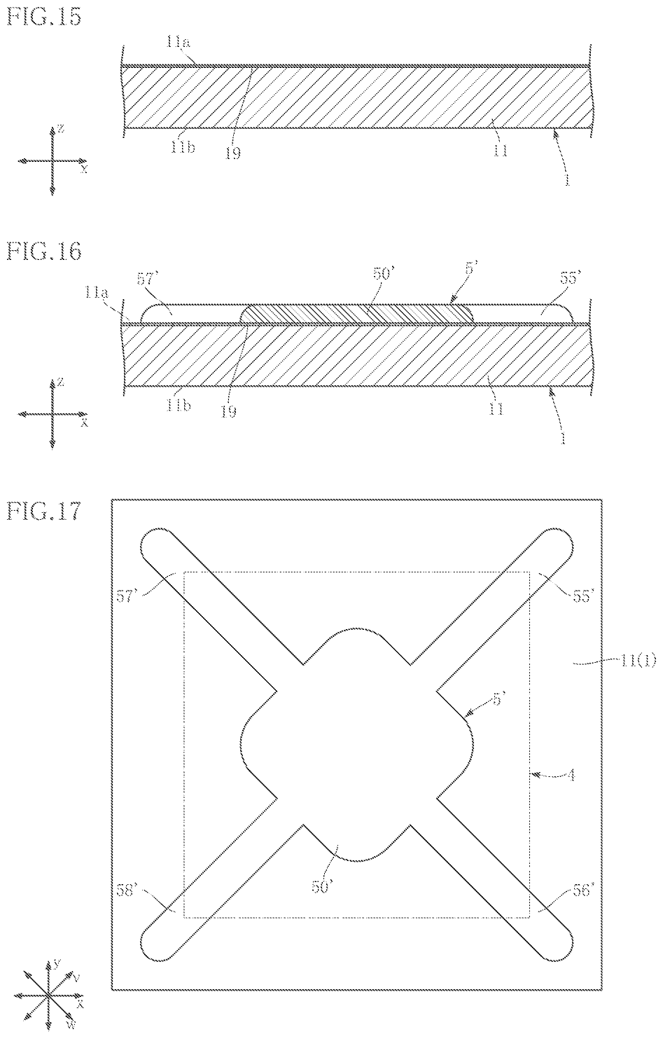

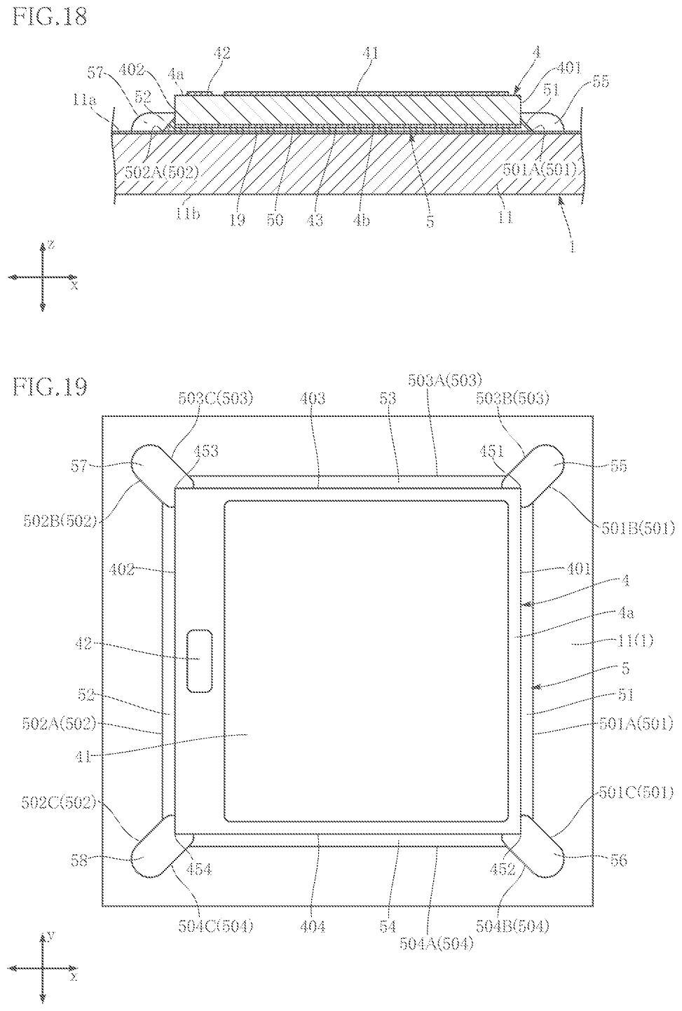

FIG. 7.

FIG. 9 is a sectional view taken along line IX-IX in FIG. 7.

FIG. 10 is a sectional view taken along line X-X in FIG. 7.

FIG. 11 is a partially enlarged view of FIG. 7.

FIG. 12 is a partially enlarged view of FIG. 7.

FIG. 13 is a partially enlarged view of FIG. 7.

FIG. 14 is a partially enlarged view of FIG. 7.

FIG. 15 is a sectional view showing a step of an example of a method for manufacturing the semiconductor device according to the first embodiment of the present disclosure.

FIG. 16 is a sectional view showing a step subsequent to the step of FIG. 15.

FIG. 17 is a schematic plan view showing the step subsequent to the step of FIG. 15.

FIG. 18 is a sectional view showing a step subsequent to the step of FIG. 16.

FIG. 19 is a schematic plan view showing the step subsequent to the step of FIG. 16.

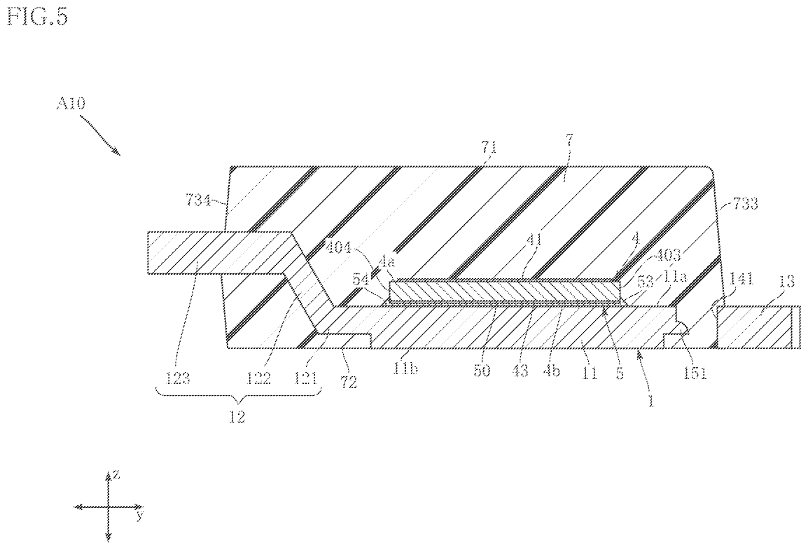

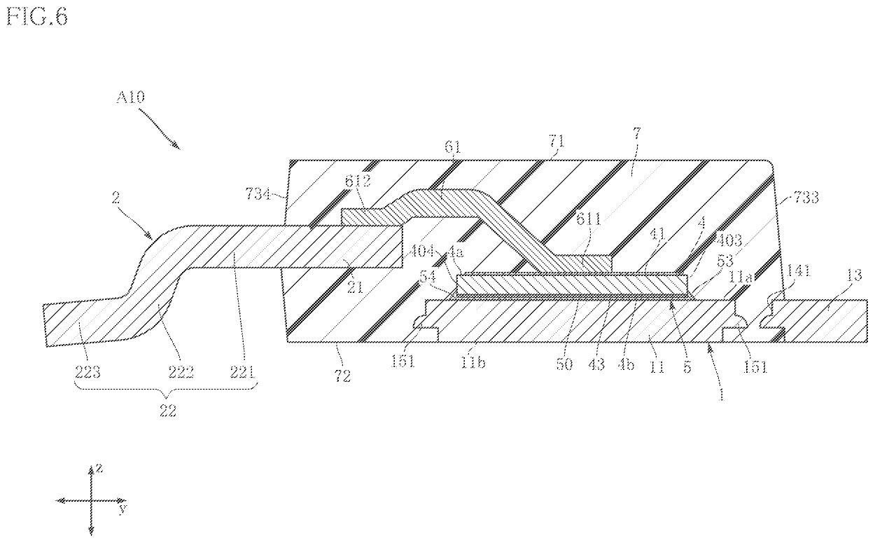

FIG. 20 is a plan view corresponding to FIG. 3, which shows a semiconductor device according to a first variation of the first embodiment.

FIG. 21 is a partially enlarged view of FIG. 20.

### DETAILED DESCRIPTION OF EMBODIMENTS

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

In the present disclosure, the phrases “an object A is formed in an object B” and “an object A is formed on an object B” include, unless otherwise specified, “an object A is formed directly in/on the object B” and “an object A is formed in/on the object B with another object interposed between the object A and the object B”. Similarly, the phrases “an object A is disposed in an object B” and “an object A is disposed on an object B” include, unless otherwise specified, “an object A is disposed directly in/on the object B” and “an object A is disposed in/on the object B with another object interposed between the object A and the object B”. Similarly, the phrase “an object A is located on an object B” includes, unless otherwise specified, “an object A is located on an object B in contact with the object B” and “an object A is located an object B with another object interposed between the object A and the object B”. Also, the phrase “an object A overlaps with an object B as viewed in a certain direction” includes, unless otherwise specified, “an object A overlaps with the entirety of an object B” and “an object A overlaps with a portion of an object B”.

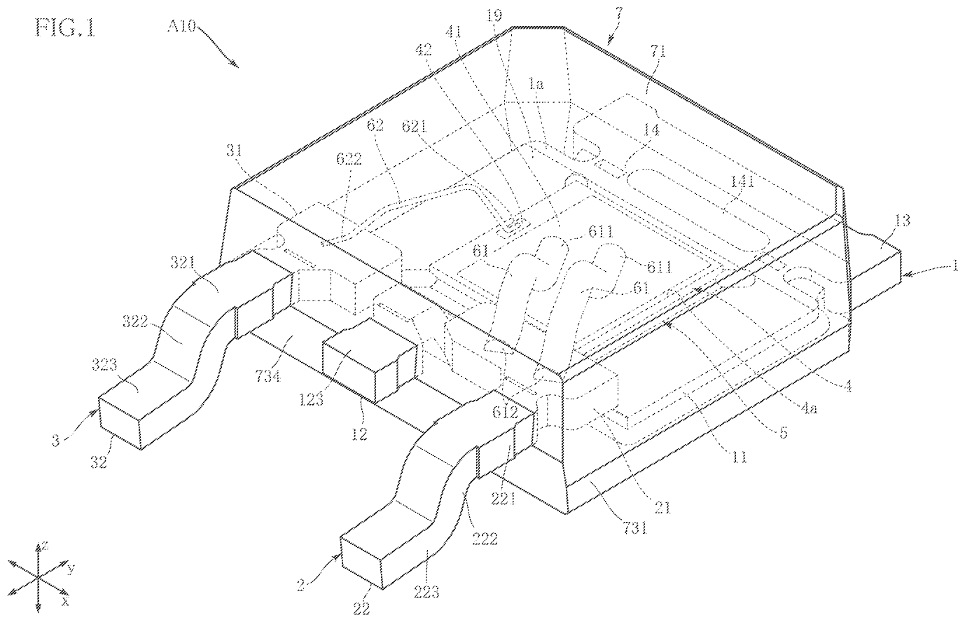

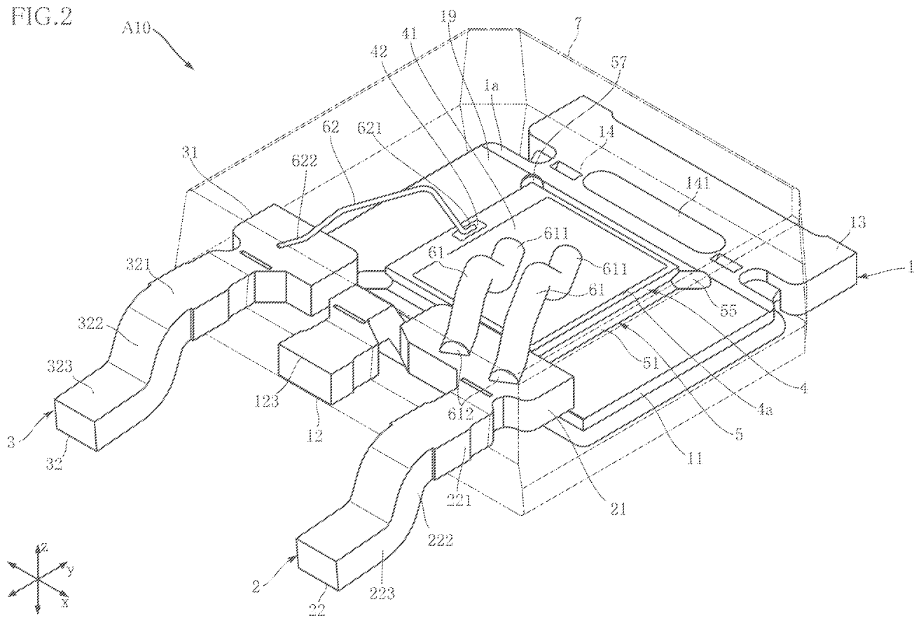

FIGS. 1 to 14 show a semiconductor device according to a first embodiment of the present disclosure. The semiconductor device A10 of the present embodiment includes a first lead 1, a second lead 2, a third lead 3, a semiconductor element 4, a conductive bonding material 5, a plurality of first conductive members 61, a second conductive member 62 and a sealing resin 7.

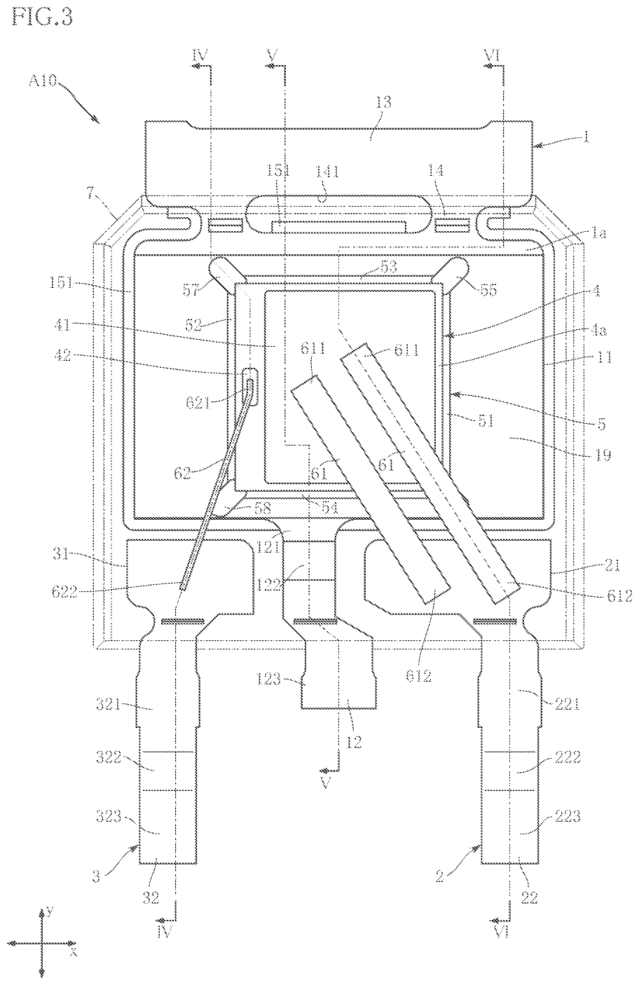

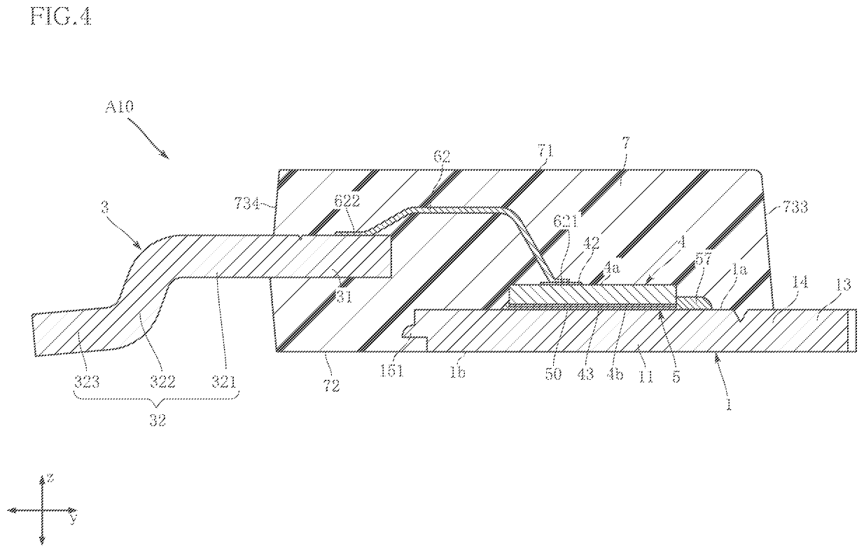

FIG. 1 is a perspective view of the semiconductor device A10. FIG. 2 is a perspective view of the semiconductor device A10. FIG. 3 is a plan view of the semiconductor device A10. FIG. 4 is a sectional view taken along line IV-IV in FIG. 3. FIG. 5 is a sectional view taken along line V-V in FIG. 3. FIG. 6 is a sectional view taken along line VI-VI in FIG. 3.

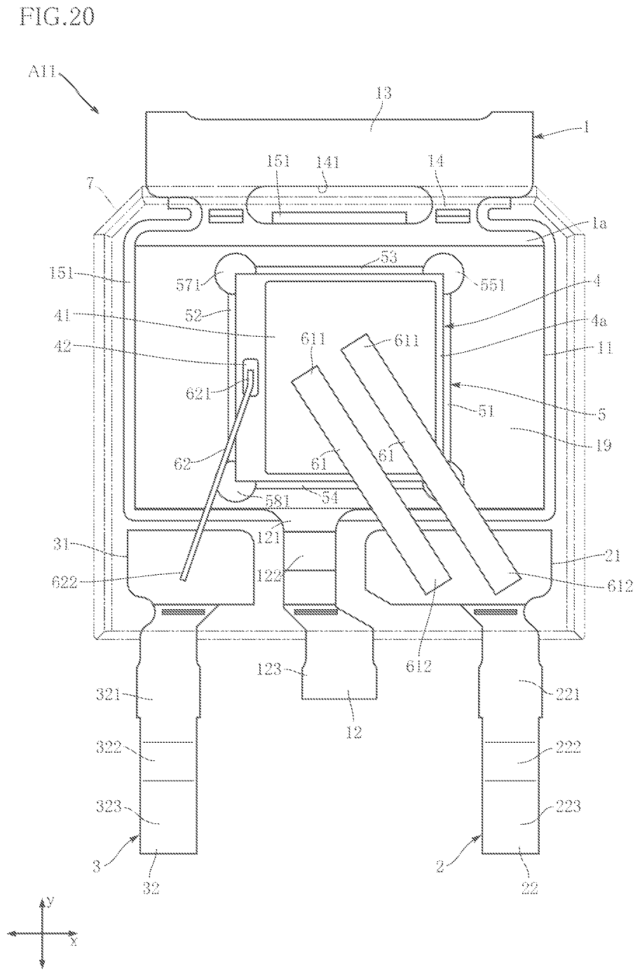

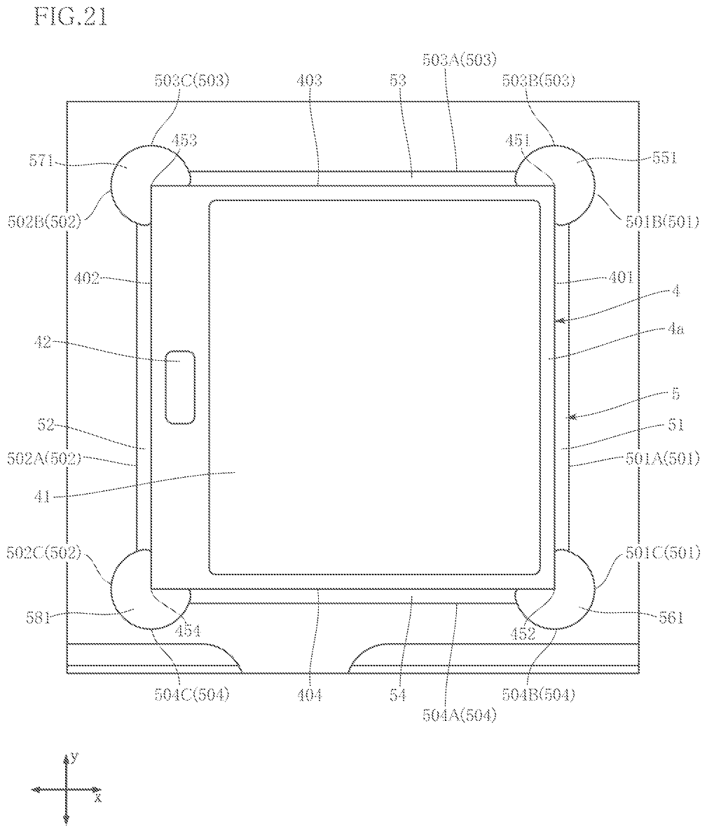

FIG. 7 is a partially enlarged view of FIG. 3. FIG. 8 is a sectional view taken along line VIII-VIII in FIG. 7. FIG. 9 is a sectional view taken along line IX-IX in FIG. 7. FIG. is a sectional view taken along line X-X in FIG. 7. FIGS. 11 to 14 are partially enlarged views of FIG. 7. In FIGS. 2 and 3, the sealing resin 7 is illustrated as transparent for convenience of understanding. In FIG. 7, the first conductive members 61 and the second conductive member 62 are omitted.

In the description of the semiconductor device A10, three directions that are orthogonal to each other are referred to as appropriate. In the illustrated examples, the thickness direction of the semiconductor element 4 is defined as the “thickness direction z”. A direction orthogonal to the thickness direction z is defined as the “first direction x”, and the direction orthogonal to the thickness direction z and the first direction x is defined as the “second direction y”.

The first lead 1, the second lead 2 and the third lead 3 are formed by punching or bending a metal plate, for example. The constituent material of the first lead 1, the second lead 2 and the third lead 3 includes, for example, Cu (copper) or Ni (nickel) or alloys of these.

The first lead 1 is a member on which the semiconductor element 4 is mounted. As shown in FIGS. 1 to 6, the first lead 1 has an element bonding portion 11, a terminal extension 12, a protruding portion 13 and a connecting portion 14. The element bonding portion 11 has an obverse surface 11a and a reverse surface 11b. The obverse surface 11a faces a first side in the thickness direction z, and the reverse surface 11b faces a second side in the thickness direction z. The semiconductor element 4 is mounted on the obverse surface 11a. The shape of the element bonding portion 11 is not particularly limited, and is rectangular (or generally rectangular) as viewed in the thickness direction z in the illustrated example. In the present embodiment, the reverse surface 11b is exposed from the sealing resin 7, as shown in FIGS. 4 to 6. When the semiconductor device A10 is mounted to e.g. a circuit board (not shown), the reverse surface 11b is bonded with a bonding material such as solder. The first lead 1 is an example of a “support member”. In the present disclosure, the support member may also be referred to as a “base” or a “substrate”.

As shown in FIGS. 3 to 6, the element bonding portion 11 of the present embodiment is formed with an engagement part 151. The engagement part 151 includes portions protruding from the periphery of the element bonding portion 11 in the first direction x or the second direction y. The engagement part 151 engages with a part of the sealing resin 7 in order that the holding force of the element bonding portion 11 by the sealing resin 7 is increased.

As shown in FIGS. 1 to 3 and 5, the terminal extension 12 extends toward a second side (the side on which pad portions 21 and 31 described later are located) in the second direction y relative to the element bonding portion 111. The configuration of the terminal extension 12 is not particularly limited. In the illustrated example, the terminal extension 12 has a root part 121, a bent part 122 and a tip part 123.

The root part 121 extends from the element bonding portion 11 toward the second side in the second direction y and has a shape along the second direction y. The bent part 122 is connected to the distal end of the root part 121 in the second direction y and bent toward the first side in the thickness direction z (the upper side in FIG. 5) as viewed in the first direction x. The tip part 123 is connected to the bent part 122 and extends along the second direction y from the bent part 122 toward the second side in the second direction y. In the illustrated example, a part of the tip part 123 protrudes from the sealing resin 7.

As shown in FIGS. 1 to 3 and 5, the protruding portion 13 is located on a first side in the second direction y relative to the element bonding portion 11. The shape of the protruding portion 13 is not particularly limited. In the illustrated example, the protruding portion 13 has a rectangular (or generally rectangular) shape elongated in the first direction x as viewed in the thickness direction z and most of it is exposed from the sealing resin 7.

The connecting portion 14 connects the element bonding portion 11 and the protruding portion 13 to each other. As shown in FIG. 3, the connecting portion 14 in the illustrated example has a through-hole 141. The through-hole 141 penetrates the connecting portion 14 in the thickness direction z.

The second lead 2 is a member to which the first conductive members 61, described later, are bonded. As shown in FIG. 3, the second lead 2 is spaced apart from the first lead 1 as viewed in the thickness direction z. As shown in FIGS. 1 to 3 and 6, the second lead 2 of the present embodiment has a pad portion 21 and a terminal portion 22. The first conductive members 61 are bonded to the pad portion 21. The shape of the pad portion 21 is not particularly limited and is rectangular (or generally rectangular) as viewed in the thickness direction z in the illustrated example. As shown in FIG. 6, the pad portion 21 is covered with the sealing resin 7 in the present embodiment.

As shown in FIGS. 1 to 3 and FIG. 6, in the present embodiment, the pad portion 21 is located on the second side in the second direction y relative to the element bonding portion 11 and on the first side in the first direction x relative to the terminal extension 12 as viewed in the thickness direction z. The pad portion 21 is offset from the element bonding portion 11 toward the first side in the thickness direction z (toward the upper side in FIG. 6).

As shown in FIGS. 1 to 3 and FIG. 6, the terminal portion 22 extends toward the second side in the second direction y relative to the pad portion 21. The terminal portion 22 may be used in mounting the semiconductor device A10 to a circuit board, for example. The shape of the terminal portion 22 is not particularly limited. In the illustrated example, the terminal portion 22 has a root part 221, a bent part 222 and a tip part 223.

The root part 221 extends from the pad portion 21 toward the second side in the second direction y and has a shape along the second direction y. The root part 221 is partially exposed from the sealing resin 7. The bent part 222 is connected to the distal end of the root part 221 in the second direction y and bent toward the second side in the thickness direction z (the lower side in FIG. 6) as viewed in the first direction x. The tip part 223 is connected to the bent part 222 and extends along the second direction y from the bent part 222 toward the second side in the second direction y.

The third lead 3 is a member to which the second conductive members 62, described later, is bonded. As shown in FIG. 3, the third lead 3 is spaced apart from the first lead 1 and the second lead 2 as viewed in the thickness direction z. As shown in FIGS. 1 to 4, the third lead 3 of the present embodiment has a pad portion 31 and a terminal portion 32. The second conductive member 62 is bonded to the pad portion 31. The shape of the pad portion 31 is not particularly limited and is rectangular (or generally rectangular) as viewed in the thickness direction z in the illustrated example. As shown in FIG. 4, the pad portion 31 is covered with the sealing resin 7 in the present embodiment.

As shown in FIGS. 1 to 4, the terminal portion 32 extends toward the second side in the second direction y relative to the pad portion 31. The terminal portion 32 may be used in mounting the semiconductor device A10 to a circuit board, for example. The shape of the terminal portion 32 is not particularly limited. In the illustrated example, the terminal portion 32 has a root part 321, a bent part 322 and a tip part 323.

The root part 321 extends from the pad portion 31 toward the second side in the second direction y and has a shape along the second direction y. The root part 321 is partially exposed from the sealing resin 7. The bent part 322 is connected to the distal end of the root part 321 in the second direction y and bent toward the second side in the thickness direction z (the lower side in FIG. 4) as viewed in the first direction x. The tip part 323 is connected to the bent part 322 and extends along the second direction y from the bent part 322 toward the second side in the second direction y.

The semiconductor element 4 is an electronic component that serves as a primary element for the function of the semiconductor device A10 and made of a semiconductor material. Examples of the semiconductor material include Si (silicon), SiC (silicon carbide) and GaAs (gallium arsenide), but the present disclosure is not limited to these. The semiconductor element 4 is, for example, a power semiconductor chip such as a MOSFET (Metal Oxide Semiconductor Field Effect Transistor). The present embodiment shows the example in which the semiconductor element 4 is a MOSFET, but the semiconductor element is not limited to this and may be other transistors such as IGBTs (Insulated Gate Bipolar Transistors) or diodes such as Schottky barrier diodes or fast recovery diodes.

As shown in FIGS. 1 to 10, the semiconductor element 4 of the present embodiment includes an element obverse surface 4a, an element reverse surface 4b, a first element side surface 401, a second element side surface 402, a third element side surface 403, a fourth element side surface 404, a first obverse surface electrode 41, a second obverse surface electrode 42 and a reverse surface electrode 43.

The semiconductor element 4 is rectangular as viewed in the thickness direction z. The element obverse surface 4a faces the first side (the upper side in FIGS. 1, 2 and 4) in the thickness direction z. The element reverse surface 4b faces the second side (the lower side in FIGS. 1, 2 and 4) in the thickness direction z, i.e., faces away from the element obverse surface 4a. The element obverse surface 4a faces the same side as the obverse surface 11a of the element bonding portion 11 in the thickness direction z. Thus, the element reverse surface 4b faces the obverse surface 11a.

The first element side surface 401 and the second element side surface 402 are spaced apart from each other in the first direction x. The first element side surface 401 faces the first side in the first direction x. The second element side surface 402 faces the second side in the first direction x. Each of the third element side surface 403 and the fourth element side surface 404 is connected to the first element side surface 401 and the second element side surface 402. The third element side surface 403 and the fourth element side surface 404 are spaced apart from each other in the second direction y. The third element side surface 403 faces the first side in the second direction y. The fourth element side surface 404 faces the second side in the second direction y.

As shown in FIGS. 1 to 3, the first obverse surface electrode 41 and the second obverse surface electrode 42 are disposed on the element obverse surface 4a. In the present embodiment, the first obverse surface electrode 41 is a source electrode and used as an input/output terminal. The first obverse surface electrode 41 covers most of the element obverse surface 4a. The second obverse surface electrode 42 is a gate electrode through which a gate voltage is applied to the semiconductor element 4 as a switching element. In the illustrated example, the second obverse surface electrode 42 is smaller than the first obverse surface electrode 41. The second obverse surface electrode 42 is offset toward the second side in the first direction x (the left side in FIG. 3) on the element obverse surface 4a.

As shown in FIGS. 4 to 6 and FIGS. 8 to 10, the reverse surface electrode 43 is disposed on the element reverse surface 4b. In the present embodiment, the reverse surface electrode 43 is a drain electrode and used as an input/output terminal together with the first obverse surface electrode 41. The reverse surface electrode 43 entirely (or almost entirely) covers the element reverse surface 4b.

The reverse surface electrode 43 is electrically bonded to the obverse surface 11a (the element bonding portion 11, the first lead 1) via the conductive bonding material 5. The conductive bonding material 5 conductively bonds the obverse surface 11a (the element bonding portion 11) and the reverse surface electrode 43 to each other. The constituent material of the conductive bonding material 5 may include Ag (silver), for example. In the semiconductor device A10, the conductive bonding material 5 is sintered silver. The conductive bonding material 5 may be made of sintered metal containing metals other than Ag, metal paste material, or solder.

In the present embodiment, as shown in FIGS. 3 and 8 to 10, the obverse surface 11a of the element bonding portion 11 is formed with a plating layer 19. The plating layer 19 is a metal layer formed by plating on a metal plate of e.g., Cu that constitutes the first lead 1. The plating layer 19 is formed at least in a region that overlaps with the conductive bonding material 5 as viewed in the thickness direction z. In the present embodiment, the plating layer 19 covers most of the obverse surface 11a. The constituent material of the plating layer 19 is not particularly limited and may be Ag or Ni, for example. The element bonding portion 11 (the first lead 1) may not be formed with the plating layer 19 on the obverse surface 11a.

As shown in FIGS. 7 to 10, the conductive bonding material 5 is disposed in a rectangular region overlapping with the semiconductor element 4 and in a region surrounding the semiconductor element 4 as viewed in the thickness direction z. As described later, the conductive bonding material 5 extends outward of the semiconductor element 4 further at or near the four corners of the semiconductor element 4 than at other locations.

As shown in FIG. 7, the conductive bonding material 5 has a first edge 501, a second edge 502, a third edge 503 and a fourth edge 504. The first edge 501 is located on the first side in the first direction x relative to the first element side surface 401 of the semiconductor element 4 as viewed in the thickness direction z. As viewed in the thickness direction z, the second edge 502 is located on the second side in the first direction x relative to the second element side surface 402. As viewed in the thickness direction z, the third edge 503 is located on the first side in the second direction y relative to the third element side surface 403, and the fourth edge 504 is located on the second side in the second direction y relative to the fourth element side surface 404.

In the present embodiment, the first edge 501 includes a first edge first portion 501A, a first edge second portion 501B and a first edge third portion 501C. The first edge first portion 501A extends in the second direction y. The first edge second portion 501B is connected to the first edge first portion 501A, located outside the first edge first portion 501A in the first direction x, and located at the end closer to the third edge 503 in the second direction y. The first edge third portion 501C is connected to the first edge first portion 501A, located outside the first edge first portion 501A in the first direction x, and located at the end closer to the fourth edge 504 in the second direction y. Thus, as shown in FIGS. 7, 11 and 12, the distance between the first element side surface 401 and the first edge 501 in the first direction x (the first distance D1) is greater at opposite ends than at the center of the first element side surface 401 in the second direction y. The first edge first portion 501A is illustrated as a straight line extending along the second direction y for convenience of illustration and explanation, but the first edge first portion 501A may include a curved portion.

As shown in FIG. 7, the second edge 502 includes a second edge first portion 502A, a second edge second portion 502B and a second edge third portion 502C. The second edge first portion 502A extends in the second direction y. The second edge second portion 502B is connected to the second edge first portion 502A, located outside the second edge first portion 502A in the first direction x, and located at the end closer to the third edge 503 in the second direction y. The second edge third portion 502C is connected to the second edge first portion 502A, located outside the second edge first portion 502A in the first direction x, and located at the end closer to the fourth edge 504 in the second direction y. Thus, as shown in FIGS. 7, 13 and 14, the distance between the second element side surface 402 and the second edge 502 in the first direction x (the second distance D2) is greater at opposite ends than at the center of the second element side surface 402 in the second direction y. The second edge first portion 502A is illustrated as a straight line extending along the second direction y for convenience of illustration and explanation, but the second edge first portion 502A may include a curved portion.

The third edge 503 includes a third edge first portion 503A, a third edge second portion 503B and a third edge third portion 503C. The third edge first portion 503A extends in the first direction x. The third edge second portion 503B is connected to the third edge first portion 503A, located outside the third edge first portion 503A in the second direction y, and located at the end closer to the first edge 501 in the first direction x. The third edge third portion 503C is connected to the third edge first portion 503A, located outside the third edge first portion 503A in the second direction y, and located at the end closer to the second edge 502 in the first direction x. Thus, as shown in FIGS. 7, 11 and 13, the distance between the third element side surface 403 and the third edge 503 in the second direction y (the third distance D3) is greater at opposite ends than at the center of the third element side surface 403 in the first direction x. The third edge first portion 503A is illustrated as a straight line extending along the first direction x for convenience of illustration and explanation, but the third edge first portion 503A may include a curved portion.

The fourth edge 504 includes a fourth edge first portion 504A, a fourth edge second portion 504B and a fourth edge third portion 504C. The fourth edge first portion 504A extends in the first direction x. The fourth edge second portion 504B is connected to the fourth edge first portion 504A, located outside the fourth edge first portion 504A in the second direction y, and located at the end closer to the first edge 501 in the first direction x. The fourth edge third portion 504C is connected to the fourth edge first portion 504A, located outside the fourth edge first portion 504A in the second direction y, and located at the end closer to the second edge 502 in the first direction x. Thus, as shown in FIGS. 7, 12 and 14, the distance between the fourth element side surface 404 and the fourth edge 504 in the second direction y (the fourth distance D4) is greater at opposite ends than at the center of the fourth element side surface 404 in the first direction x. The fourth edge first portion 504A is illustrated as a straight line extending along the first direction x for convenience of illustration and explanation, but the fourth edge first portion 504A may include a curved portion.

In the present embodiment, the first edge second portion 501B has a first edge first inclined portion 501d, as shown in FIG. 11. As viewed in the thickness direction z, the first edge first inclined portion 501d is connected to the first edge first portion 501A and extends in a third direction v that crosses both the first direction x and the second direction y. The angle between the first direction x and the third direction v and the angle between the second direction y and the third direction v are not particularly limited, but are both 45° in the present embodiment. As shown in FIG. 12, the first edge third portion 501C has a first edge second inclined portion 501e. As viewed in the thickness direction z, the first edge second inclined portion 501e is connected to the first edge first portion 501A and extends in a fourth direction w that crosses both the first direction x and the second direction y. The angle between the first direction x and the fourth direction w and the angle between the second direction y and the fourth direction w are not particularly limited, but are both 45° in the present embodiment. In the present embodiment, the angle between the third direction v and the fourth direction w is 90°.

As shown in FIG. 13, the second edge second portion 502B has a second edge first inclined portion 502d. The second edge first inclined portion 502d is connected to the second edge first portion 502A and extends in the fourth direction w as viewed in the thickness direction z. As shown in FIG. 14, the second edge third portion 502C has a second edge second inclined portion 502e. The second edge second inclined portion 502e is connected to the second edge first portion 502A and extends in the third direction v as viewed in the thickness direction z.

As shown in FIG. 11, the third edge second portion 503B has a third edge first inclined portion 503d. The third edge first inclined portion 503d is connected to the third edge first portion 503A and extends in the third direction v as viewed in the thickness direction z. As shown in FIG. 13, the third edge third portion 503C has a third edge second inclined portion 503e. The third edge second inclined portion 503e is connected to the third edge first portion 503A and extends in the fourth direction w as viewed in the thickness direction z.

As shown in FIG. 12, the fourth edge second portion 504B has a fourth edge first inclined portion 504d. The fourth edge first inclined portion 504d is connected to the fourth edge first portion 504A and extends in the fourth direction w as viewed in the thickness direction z. As shown in FIG. 14, the fourth edge third portion 504C has a fourth edge second inclined portion 504e. The fourth edge second inclined portion 504e is connected to the fourth edge first portion 504A and extends in the third direction v as viewed in the thickness direction z.

As shown in FIGS. 7 to 10, in the present embodiment, the conductive bonding material 5 has an overlapping portion 50, a first intermediate portion 51, a second intermediate portion 52, a third intermediate portion 53, a fourth intermediate portion 54, a first extension 55, a second extension 56, a third extension 57 and a fourth extension 58. The overlapping portion 50 overlaps with the entirety of the semiconductor element 4 as viewed in the thickness direction z. The first intermediate portion 51, the second intermediate portion 52, the third intermediate portion 53, the fourth intermediate portion 54, the first extension 55, the second extension 56, the third extension 57 and the fourth extension 58 are all located outside the overlapping portion 50 as viewed in the thickness direction z and connected to the overlapping portion 50.

The first intermediate portion 51 is located between the first element side surface 401 of the semiconductor element 4 and the first edge first portion 501A as viewed in the thickness direction z. The second intermediate portion 52 is located between the second element side surface 402 and the second edge first portion 502A as viewed in the thickness direction z. The third intermediate portion 53 is located between the third element side surface 403 and the third edge first portion 503A as viewed in the thickness direction z. The fourth intermediate portion 54 is located between the fourth element side surface 404 and the fourth edge first portion 504A as viewed in the thickness direction z.

As shown in FIGS. 7 and 11, the first extension 55 extends outward in the third direction v from a first corner 451 that is the boundary between the first element side surface 401 and the third element side surface 403. The first extension 55 includes the first edge first inclined portion 501d and the third edge first inclined portion 503d. As shown in FIGS. 7 and 12, the second extension 56 extends outward in the fourth direction w from a second corner 452 that is the boundary between the first element side surface 401 and the fourth element side surface 404. The second extension 56 includes the first edge second inclined portion 501e and the fourth edge first inclined portion 504d. As shown in FIGS. 7 and 13, the third extension 57 extends outward in the fourth direction w from a third corner 453 that is the boundary between the second element side surface 402 and the third element side surface 403. The third extension 57 includes the second edge first inclined portion 502d and the third edge second inclined portion 503e. As shown in FIGS. 7 and 14, the fourth extension 58 extends outward in the third direction v from a fourth corner 454 that is the boundary between the second element side surface 402 and the fourth element side surface 404. The fourth extension 58 includes the second edge second inclined portion 502e and the fourth edge second inclined portion 504e.

In the figures such as FIGS. 7 and 11, the boundary between the first extension 55 and the first intermediate portion 51 or the third intermediate portion 53 connected to the first extension is shown by a solid line for convenience of illustration. However, the first extension 55 and the first intermediate portion 51 or the third intermediate portion 53 may not have a geometrically distinct boundary but may be connected to each other with a smooth curved surface. Also, the second extension 56 and the first intermediate portion 51 or the fourth intermediate portion 54 may not have a geometrically distinct boundary but may be connected to each other with a smooth curved surface, which holds for the third extension 57 and the second intermediate portion 52 or the third intermediate portion 53, and the fourth extension 58 and the second intermediate portion 52 or the fourth intermediate portion 54.

The distance (the first extension length L1) from the first corner 451 to the extremity of the first extension 55 in the third direction v shown in FIGS. 7 and 11 is, for example, 0.01 to 1 times the length of the diagonal of the semiconductor element 4 (hereinafter referred to as the “diagonal length Ld”). The distance (the second extension length L2) from the second corner 452 to the extremity of the second extension 56 in the fourth direction w shown in FIGS. 7 and 12 is, for example, 0.01 to 1 times the diagonal length Ld. Also, each of the distance (the third extension length L3) from the third corner 453 to the extremity of the third extension 57 in the fourth direction w shown in FIGS. 7 and 13 and the distance (the fourth extension length L4) from the fourth corner 454 to the extremity of the fourth extension 58 in the third direction v shown in FIGS. 7 and 14 is 0.01 to 1 times the diagonal length Ld. The first extension length L1, the second extension length L2, the third extension length L3, the fourth extension length L4 and the diagonal length Ld are not particularly limited. In the present embodiment, each of the first extension length L1, the second extension length L2, the third extension length L3 and the fourth extension length L4 is about 50 μm to 5000 μm, and the diagonal length Ld is about 50 μm to 15000 μm. The ratio of each of the first extension length L1, the second extension length L2, the third extension length L3 and the fourth extension length L4 to the diagonal length Ld increases as the size (the diagonal length Ld) of semiconductor device 4 decreases. This is because while the size (the diagonal length Ld) of the semiconductor element 4 varies largely depending on the type or the like of the semiconductor element 4, the degree of variation of the first extension length L1, the second extension length L2, the third extension length L3 and the fourth extension length L4 is small as compared with the degree of variation of the size (the diagonal length Ld) of the semiconductor element 4.

As shown in FIGS. 8 to 10, the thickness of each of the first extension 55, the second extension 56, the third extension 57 and the fourth extension 58 is greater than the thicknesses of the first intermediate portion 51, the second intermediate portion 52, the third intermediate portion 53 and the fourth intermediate portion 54. In the present embodiment, the thickness of each of the first extension 55, the second extension 56, the third extension 57 and the fourth extension 58 is not greater than ⅔ of the thickness of the semiconductor element 4.

The first conductive members 61 electrically connect the first obverse surface electrode 41 of the semiconductor element 4 and the second lead 2 to each other. The specific configuration of the first conductive members 61 is not particularly limited and may be a wire or ribbon made of metal, for example. Examples of the metal that forms the first conductive member 61 include Au (gold), Al (aluminum), or alloys of these. In the present embodiment, the first conductive members 61 are wires made of Al or Al alloy. In this case, the diameter of the first conductive members 61 is greater than the diameter of the second conductive member 62.

As shown in FIGS. 1 to 3 and 6, each of the first conductive members 61 has a first bonding portion 611 and a second bonding portion 612. The first bonding portion 611 is bonded to the first obverse surface electrode 41 of the semiconductor element 4. The second bonding portion 612 is bonded to the pad portion 21 of the second lead 2. The present embodiment illustrates the example in which two first conductive members 61 are provided, but configurations including a single first conductive member 61 or three or more first conductive members 61 may be employed.

The second conductive member 62 electrically connects the second obverse surface electrode 42 of the semiconductor element 4 and the third lead 3 to each other. The specific configuration of the second conductive member 62 is not particularly limited and may be a wire or ribbon made of metal, for example. Examples of the metal that forms the second conductive member 62 include Au (gold), Al (aluminum), or alloys of these. In the present embodiment, the second conductive member 62 is a wire made of Au.

As shown in FIGS. 1 to 4, the second conductive member 62 has a first bonding portion 621 and a second bonding portion 622. The first bonding portion 621 is bonded to the second obverse surface electrode 42 of the semiconductor element 4. The second bonding portion 622 is bonded to the pad portion 31 of the third lead 3.

The sealing resin 7 covers the semiconductor element 4, the first conductive members 61, the second conductive member 62 and a part of each of the first lead 1, the second lead 2 and the third lead 3. The sealing resin 7 is a thermosetting synthetic resin with electrical insulation properties. In the present embodiment, the sealing resin 7 is a black epoxy resin and may be mixed with a filler as appropriate.

As shown in FIGS. 1 and 4 to 6, the sealing resin 7 has a resin obverse surface 71, a resin reverse surface 72 and resin side surfaces 731 to 734. The resin obverse surface 71 and the resin reverse surface 72 face away from each other and are spaced apart in the thickness direction z. The resin obverse surface 71 faces in the same direction as the element obverse surface 4a, and the resin reverse surface 72 faces in the same direction as the element reverse surface 4b. Each of the resin side surfaces 731 to 734 is sandwiched between the resin obverse surface 71 and the resin reverse surface 72. The resin side surface 731 faces the first side in the first direction x. The resin side surface 732 faces the second side in the first direction x. The resin side surface 733 faces the first side in the second direction y. The resin side surface 734 faces the second side in the second direction y. In the present embodiment, the reverse surface 11b of the element bonding portion 11 is exposed at the resin reverse surface 72. The protruding portion 13 protrudes from the resin side surface 733. The terminal extension 12, the terminal portion 22 and the terminal portion 32 protrude from the resin side surface 734.

A method for manufacturing the semiconductor device A10 is described below with reference to FIGS. 15 to 19. Each of FIGS. 15, 16 and 18 is a sectional view that can be compared to the sectional view shown in FIG. 8 and shows a step of the manufacturing method of the semiconductor device A10. Each of FIGS. 17 and 19 is a plan view that can be compared to the partially enlarged plan view of FIG. 7 and shows a step of the manufacturing method of the semiconductor device A10.

First, the first lead 1 is prepared as shown in FIG. 15. In this step, a lead frame having a shape including the first lead 1 shown in FIG. 15, the second lead 2 and the third lead 3 is prepared. In the present embodiment, the obverse surface 11a of the first lead 1 (the element bonding portion 11) is formed with the plating layer 19.

Next, as shown in FIGS. 16 and 17, a conductive bonding material 5′ is disposed on the obverse surface 11a of the first lead 1 (the element bonding portion 11). The conductive bonding material 5′ is disposed on the obverse surface 11a by applying an electrically-conductive metal material in the form of a paste (e.g., Ag paste) with a dispenser, for example. In the illustrated example, the conductive bonding material 5′ disposed on the obverse surface 11a has a central portion 50′ and extensions 55′ to 58′. The central portion 50′ corresponds to a central part of the area on which the semiconductor element 4 will be disposed in a later step. In FIG. 17, the position at which the semiconductor element 4 will be disposed is shown by two-dot chain lines. The extensions 55′ to 58′ extend from the positions respectively corresponding to the four corners of the rectangular shape of the semiconductor element 4 toward the outside of the semiconductor element 4. In the example shown in FIG. 17, the extension 55′ and the extension 58′ extend in a straight line along the third direction v and can be formed continuously using a dispenser. The extension 56′ and the extension 57′ extend in a straight line along the fourth direction w and can be formed continuously using a dispenser. The size and shape of the central portion 50′ is not limited to the illustrated example and may be varied as appropriate.

Next, the semiconductor element 4 is prepared and disposed on the conductive bonding material 5′. The semiconductor element 4 is rectangular as viewed in the thickness direction z and has the element obverse surface 4a, the element reverse surface 4b, the first element side surface 401, the second element side surface 402, the third element side surface 403, the fourth element side surface 404, the first obverse surface electrode 41, the second obverse surface electrode 42 and the reverse surface electrode 43 as described above. In this step, the reverse surface electrode 43 is disposed on the conductive bonding material 5′. Next, the conductive bonding material 5′ is heated (baked) to bond the obverse surface 11a and the reverse surface electrode 43 with the conductive bonding material 5, as shown in FIGS. 18 and 19. When the conductive bonding material 5′ is heated (baked), the portion of the conductive bonding material 5′ that overlaps with the semiconductor element 4 in the thickness direction z (i.e., the central portion 50′ and a part of each extension 55′ to 58′) spreads over the obverse surface 11a, thereby protruding from each of the element side surfaces 401 to 404 of the semiconductor element 4 as viewed in the thickness direction. Subsequently, cooling is performed, whereby the conductive bonding material 5 is obtained that has the overlapping portion 50, the first intermediate portion 51, the second intermediate portion 52, the third intermediate portion 53, the fourth intermediate portion 54, the first extension 55, the second extension 56, the third extension 57 and the fourth extension 58.

Next, the first conductive members 61 and the second conductive member 62 are bonded. Next, the sealing resin 7 is formed by molding. Next, the lead frame is cut as appropriate, whereby the first lead 1, the second lead 2 and the third lead 3 are separated from each other. Through the steps described above, the semiconductor device A10 shown in FIGS. 1 to 14 is obtained.

Next, the operation and effect of the present embodiment will be described.

The semiconductor device A10 includes the first lead 1, the semiconductor element 4 and the conductive bonding material 5. The conductive bonding material 5 has the first edge 501, the second edge 502, the third edge 503 and the fourth edge 504. The first edge 501 is located on the first side in the first direction x relative to the first element side surface 401 as viewed in the thickness direction z. The second edge 502 is located on the second side in the first direction x relative to the second element side surface 402 as viewed in the thickness direction z. The third edge 503 is located on the first side in the second direction y relative to the third element side surface 403 as viewed in the thickness direction z. The fourth edge 504 is located on the second side in the second direction y relative to the fourth element side surface 404 as viewed in the thickness direction z. The distance between the first element side surface 401 and the first edge 501 in the first direction x (the first distance D1) is greater at opposite ends than at the center of the first element side surface 401 in the second direction y. The distance between the second element side surface 402 and the second edge 502 in the first direction x (the second distance D2) is greater at opposite ends than at the center of the second element side surface 402 in the second direction y. The distance between the third element side surface 403 and the third edge 503 in the second direction y (the third distance D3) is greater at opposite ends than at the center of the third element side surface 403 in the first direction x. The distance between the fourth element side surface 404 and the fourth edge 504 in the second direction y (the fourth distance D4) is greater at opposite ends than at the center of the fourth element side surface 404 in the first direction x.

With such a configuration, the conductive bonding material 5 extends outward of the semiconductor element 4 further at or near the four corners of the semiconductor element 4 than at other locations as viewed in the thickness direction z. Thus, the thermal stress of the conductive bonding material 5, which may be produced during the manufacture of the semiconductor device A10 because of the difference in coefficient of linear expansion between the lead 1 and the conductive bonding material 5, can be reduced near the four corners of the semiconductor element 4. Thus, according to the present embodiment, the separation or the like of the conductive bonding material 5, which conductively bonds the first lead 1 and the semiconductor element 4, is eliminated or reduced.

The conductive bonding material 5 has the first intermediate portion 51, the second intermediate portion 52, the third intermediate portion 53, the fourth intermediate portion 54, the first extension 55, the second extension 56, the third extension 57 and the fourth extension 58. The first extension 55 extends outward in the third direction v from the first corner 451 that is the boundary between the first element side surface 401 and the third element side surface 403. The second extension 56 extends outward in the fourth direction w from the second corner 452 that is the boundary between the first element side surface 401 and the fourth element side surface 404. The third extension 57 extends outward in the fourth direction w from the third corner 453 that is the boundary between the second element side surface 402 and the third element side surface 403. The fourth extension 58 extends outward in the third direction v from the fourth corner 454 that is the boundary between the second element side surface 402 and the fourth element side surface 404. Thus, as viewed in the thickness direction z, the first extension 55 and the fourth extension 58 extending from a pair of diagonally opposite corners of the semiconductor element 4 extend in the same direction (the third direction v). The second extension 56 and the third extension 57 extending from another pair of diagonally opposite corners of the semiconductor element 4 extend in the same direction (the fourth direction w). With such a configuration, the conductive bonding material 5 can be easily formed by applying the material of the conductive bonding material 5 along fixed directions.

In the conductive bonding material 5 of the present embodiment, as viewed in the thickness direction z, each of the first extension length L1 of the first extension 55 from a corner (the first corner 451) of the semiconductor element 4, the second extension length L2 of the second extension 56 from a corner (the second corner 452) of the semiconductor element 4, the third extension length L3 of the third extension 57 from a corner (the third corner 453) of the semiconductor element 4 and the fourth extension length L4 of the fourth extension 58 from a corner (the fourth corner 454) of the semiconductor element 4 is 0.01 to 1 times the diagonal length Ld of the semiconductor element 4. With such a configuration, the periphery of the conductive bonding material 5 is located away from the four corners of the semiconductor element 4 by an appropriate distance. Thus, the separation or the like of the conductive bonding material caused by thermal stress can be reliably eliminated or reduced.

According to the technique of applying the material with a dispenser to form the conductive bonding material 5, the first extension 55, the second extension 56, the third extension 57 and the fourth extension 58 having the size suitable for the semiconductor element 4 can be easily formed even if the size of the semiconductor element 4 is changed.

In the present embodiment, the thickness of each of the first extension 55, the second extension 56, the third extension 57 and the fourth extension 58 of the conductive bonding material 5 is greater than the thicknesses of all of the first intermediate portion 51, the second intermediate portion 52, the third intermediate portion 53 and the fourth intermediate portion 54. With such a configuration, the volume occupied by the first extension 55, the second extension 56, the third extension 57 and the fourth extension 58 is relatively large as compared with other portions. Thus, a reduction in the influence of thermal stress can be expected for the first extension 55, the second extension 56, the third extension 57 and the fourth extension 58, which are located near the four corners of the semiconductor element 4.

The thickness of each of the first extension 55, the second extension 56, the third extension 57 and the fourth extension 58 is not greater than ⅔ of the thickness of the semiconductor element 4. Such a configuration prevents undesired electrical connection between the conductive bonding material 5 (the first extension 55, the second extension 56, the third extension 57 and the fourth extension 58) and the first obverse surface electrode 41 or other elements on the element obverse surface 4a side of the semiconductor element 4.

Of the obverse surface 11a of the element bonding portion 11 (the first lead 1), at least the region that overlaps with the conductive bonding material 5 as viewed in the thickness direction z is formed with the plating layer 19. With such a configuration, when the conductive bonding material 5 is formed on the obverse surface 11a, the shape of the conductive bonding material 5 can be expected to be stabilized due to, for example, improvement in the wettability of the surface on the element bonding portion 11.

FIGS. 20 and 21 show a semiconductor device according to a variation of the first embodiment. FIG. 20 is a plan view corresponding to FIG. 3 of the foregoing embodiment. FIG. 21 is a partially enlarged view of FIG. 20. In FIG. 20 and the subsequent drawing, the elements that are identical or similar to those of the semiconductor device A10 of the foregoing embodiment are denoted by the same reference signs, and the descriptions thereof are omitted.

In the semiconductor device A11 of the present variation, the shape of the conductive bonding material 5 partially differs from the semiconductor device A10 of the foregoing embodiment. In the present variation, the shape of the conductive bonding material 5 near the four corners as viewed in the thickness direction z differs from that shown in FIG. 7.

As shown in FIG. 21, in the present variation, each of the first edge second portion 501B and the first edge third portion 501C has an arcuate shape. Similarly, each of the second edge second portion 502B and the second edge third portion 502C, the third edge second portion 503B and the third edge third portion 503C, as well as the fourth edge second portion 504B and the fourth edge third portion 504C has an arcuate shape.

The conductive bonding material 5 has an extension 551, an extension 561, an extension 571 and an extension 581. The extension 551 includes the first edge second portion 501B and the third edge second portion 503B and bulges toward the outside of the semiconductor element 4 near the first corner 451 of the semiconductor element 4 as viewed in the thickness direction z. The extension 561 includes the first edge third portion 501C and the fourth edge second portion 504B and bulges toward the outside of the semiconductor element 4 near the second corner 452 of the semiconductor element 4 as viewed in the thickness direction z. The extension 571 includes the second edge second portion 502B and the first edge third portion 501C and bulges toward the outside of the semiconductor element 4 near the third corner 453 of the semiconductor element 4 as viewed in the thickness direction z. The extension 581 includes the second edge third portion 502C and the fourth edge third portion 504C and bulges toward the outside of the semiconductor element 4 near the fourth corner 454 of the semiconductor element 4 as viewed in the thickness direction z.

In the present variation again, the conductive bonding material 5 extends outward from the semiconductor element 4 further at or near the four corners of the semiconductor element 4 than at other locations as viewed in the thickness direction z. Thus, the thermal stress of the conductive bonding material 5, which may be produced during the manufacture of the semiconductor device A11 because of the difference in coefficient of linear expansion between the lead 1 and the conductive bonding material 5, can be reduced at the four corners of the semiconductor element 4. Thus, according to the present variation, the separation or the like of the conductive bonding material 5, which conductively connects the first lead 1 and the semiconductor element 4, is eliminated or reduced. Moreover, the effects similar to the semiconductor device A10 of the above-described embodiment can be obtained by the configuration similar to the above-described embodiment.

The semiconductor device according to the present disclosure is not limited to the foregoing embodiments. The specific configuration of each part of the semiconductor device according to the present disclosure may be varied in design in many ways.

In the foregoing embodiments, the first lead 1 made of a metal plate is described as the support member on which the semiconductor element 4 is disposed. However, the configuration of the support member is not particularly limited. For example, a DBC (Direct Bonded Copper) plate may be used instead of the first lead 1. When a DBC plate is used, the separation or the like of the conductive bonding material 5 that conductively bonds the DBC substrate and the semiconductor element 4 is eliminated or reduced.

The foregoing embodiments describe the semiconductor devices A10 and A11 having a single semiconductor element 4. However, the present disclosure is applicable to a semiconductor device with a plurality of semiconductor elements. Instead of the application using a dispenser as described above, other techniques may be used to form the conductive bonding material 5. For example, the conductive bonding material 5 having a predetermined shape may be disposed on the obverse surface of the support member by using a mask.

The present disclosure includes the embodiments described in the following clauses.

Clause 1.

A semiconductor device comprising:
a support member including an obverse surface facing one side in a thickness direction;
a semiconductor element including an element obverse surface and an element reverse surface that face away from each other in the thickness direction and a reverse surface electrode disposed on the element reverse surface; and
a conductive bonding material that conductively bonds the obverse surface of the support member and the reverse surface electrode to each other, wherein
the semiconductor element includes a first element side surface and a second element side surface that face a first side and a second side, respectively, in a first direction orthogonal to the thickness direction, and a third element side surface and a fourth element side surface that face a first side and a second side, respectively, in a second direction orthogonal to the thickness direction and the first direction,
as viewed in the thickness direction, the conductive bonding material includes a first edge located on the first side in the first direction relative to the first element side surface, a second edge located on the second side in the first direction relative to the second element side surface, a third edge located on the first side in the second direction relative to the third element side surface, and a fourth edge located on the second side in the second direction relative to the fourth element side surface,
a first distance between the first element side surface and the first edge in the first direction is greater at opposite ends than at a center of the first element side surface in the second direction,
a second distance between the second element side surface and the second edge in the first direction is greater at opposite ends than at a center of the second element side surface in the second direction,
a third distance between the third element side surface and the third edge in the second direction is greater at opposite ends than at a center of the third element side surface in the first direction, and
a fourth distance between the fourth element side surface and the fourth edge in the second direction is greater at opposite ends than at a center of the fourth element side surface in the first direction.

Clause 2.

The semiconductor device according to clause 1, wherein
the first edge includes a first edge first portion, a first edge second portion and a first edge third portion, the first edge first portion extending in the second direction, the first edge second portion and the first edge third portion being connected to the first edge first portion, located outside the first edge first portion in the first direction, and located at an end closer to the third edge and at an end closer to the fourth edge, respectively, in the second direction,
the second edge includes a second edge first portion, a second edge second portion and a second edge third portion, the second edge first portion extending in the second direction, the second edge second portion and the second edge third portion being connected to the second edge first portion, located outside the second edge first portion in the first direction, and located at an end closer to the third edge and at an end closer to the fourth edge, respectively, in the second direction,
the third edge includes a third edge first portion, a third edge second portion and a third edge third portion, the third edge first portion extending in the first direction, the third edge second portion and the third edge third portion being connected to the third edge first portion, located outside the third edge first portion in the second direction, and located at an end closer to the first edge and at an end closer to the second edge, respectively, in the second direction, and
the fourth edge includes a fourth edge first portion, a fourth edge second portion and a fourth edge third portion, the fourth edge first portion extending in the first direction, the fourth edge second portion and the fourth edge third portion being connected to the fourth edge first portion, located outside the fourth edge first portion in the second direction, and located at an end closer to the first edge and at an end closer to the second edge, respectively, in the second direction.

Clause 3.

The semiconductor device according to clause 2, wherein the first edge second portion includes a first edge first inclined portion connected to the first edge first portion and extending in a third direction crossing the first direction and the second direction as viewed in the thickness direction,
the first edge third portion includes a first edge second inclined portion connected to the first edge first portion and extending in a fourth direction crossing the first direction and the second direction as viewed in the thickness direction,
the second edge second portion includes a second edge first inclined portion connected to the second edge first portion and extending in the fourth direction as viewed in the thickness direction,
the second edge third portion includes a second edge second inclined portion connected to the second edge first portion and extending in the third direction as viewed in the thickness direction,
the third edge second portion includes a third edge first inclined portion connected to the third edge first portion and extending in the third direction as viewed in the thickness direction,
the third edge third portion includes a third edge second inclined portion connected to the third edge first portion and extending in the fourth direction as viewed in the thickness direction,
the fourth edge second portion includes a fourth edge first inclined portion connected to the fourth edge first portion and extending in the fourth direction as viewed in the thickness direction, and
the fourth edge third portion includes a fourth edge second inclined portion connected to the fourth edge first portion and extending in the third direction as viewed in the thickness direction.

Clause 4.

The semiconductor device according to clause 3, wherein
as viewed in the thickness direction, the conductive bonding material includes: a first intermediate portion located between the first element side surface and the first edge first portion, a second intermediate portion located between the second element side surface and the second edge first portion, a third intermediate portion located between the third element side surface and the third edge first portion, a fourth intermediate portion located between the fourth element side surface and the fourth edge first portion;
a first extension including the first edge first inclined portion and the third edge first inclined portion and extending outward in the third direction from a first corner that is a boundary between the first element side surface and the third element side surface;
a second extension including the first edge second inclined portion and the fourth edge first inclined portion and extending outward in the fourth direction from a second corner that is a boundary between the first element side surface and the fourth element side surface;
a third extension including the second edge first inclined portion and the third edge second inclined portion and extending outward in the fourth direction from a third corner that is a boundary between the second element side surface and the third element side surface; and
a fourth extension including the second edge second inclined portion and the fourth edge second inclined portion and extending outward in the third direction from a fourth corner that is a boundary between the second element side surface and the fourth element side surface.

Clause 5.

The semiconductor device according to clause 4, wherein as viewed in the thickness direction, each of a first extension length from the first corner to an extremity of the first extension in the third direction, a second extension length from the second corner to an extremity of the second extension in the fourth direction, a third extension length from the third corner to an extremity of the third extension in the fourth direction, and a fourth extension length from the fourth corner to an extremity of the fourth extension in the third direction is 0.01 to 1 times a diagonal length from the first corner to the third corner of the semiconductor element.

Clause 6.

The semiconductor device according to clause 4 or 5, wherein a thickness of each of the first extension, the second extension, the third extension and the fourth extension is greater than a thickness of the first intermediate portion, the second intermediate portion, the third intermediate portion and the fourth intermediate portion.

Clause 7.

The semiconductor device according to clause 6, wherein the thickness of each of the first extension, the second extension, the third extension and the fourth extension is not greater than ⅔ of a thickness of the semiconductor element.

Clause 8.

The semiconductor device according to any one of clauses 1 to 7, wherein the conductive bonding material contains silver.

Clause 9.

The semiconductor device according to any one of clauses 1 to 8, wherein the conductive bonding material comprises a sintered metal.

Clause 10.

The semiconductor device according to any one of clauses 1 to 9, wherein the support member is a first lead including the obverse surface of the support member and made of a metal plate.

Clause 11.

The semiconductor device according to clause 10, wherein the obverse surface of the first lead includes a region overlapping with the conductive bonding material as viewed in the thickness direction, and the region is formed with a plating layer.

Clause 12.

The semiconductor device according to clause 10 or 11, further comprising: a second lead spaced apart from the first lead as viewed in the thickness direction and made of a metal plate; and a first conductive member, wherein
the semiconductor element includes a first obverse surface electrode disposed on the element obverse surface, and
the first conductive member is connected to the first obverse surface electrode and the second lead.

Clause 13.

The semiconductor device according to clause 12, further comprising: a third lead spaced apart from the first lead and the second lead as viewed in the thickness direction and made of a metal plate; and
a second conductive member, wherein
the semiconductor element includes a second obverse surface electrode disposed on the element obverse surface, and
the second conductive member is connected to the second obverse surface electrode and the third lead.

Clause 14.

The semiconductor device according to clause 13, wherein the reverse surface electrode is a drain electrode, the first obverse surface electrode is a source electrode, and the second obverse surface electrode is a gate electrode.

Clause 15.

A method for manufacturing a semiconductor device, the method comprising the steps of:
preparing a support member including an obverse surface facing one side in a thickness direction;
disposing a conductive bonding material on the obverse surface;
disposing a semiconductor element on the support member, the semiconductor element including an element obverse surface and an element reverse surface that face away from each other in the thickness direction and a reverse surface electrode disposed on the element reverse surface and being rectangular as viewed in the thickness direction, the semiconductor element being disposed such that the reverse surface electrode is on the conductive bonding material; and
heating the conductive bonding material to bond the obverse surface of the support member and the reverse surface electrode to each other with the conductive bonding material,
wherein disposing the conductive bonding material includes forming, in the conductive bonding material, extensions that extend from positions respectively corresponding to four corners of the semiconductor element toward an outside of the semiconductor element as viewed in the thickness direction.

### REFERENCE NUMERALS

A10, A11: Semiconductor device
1: First lead (Support member)
11: Element bonding portion 11a: Obverse surface
11b: Reverse surface 12: Terminal extension
121: Root part 122: Bent part
123: Tip part 13: Protruding portion
14: Connecting portion 141: Through-hole
151: Engagement part 19: Plating layer
2: Second lead 21: Pad portion
22: Terminal portion 221: Root part
222: Bent part 223: Tip part
3: Third lead 31: Pad portion
32: Terminal portion 321: Root part
322: Bent part 323: Tip part
4: Semiconductor element 4a: Element obverse surface
4b: Element reverse surface 401: First element side surface
402: Second element side surface
403: Third element side surface
404: Fourth element side surface
41: First obverse surface electrode
42: Second obverse surface electrode
43: Reverse surface electrode
43′: Third metal layer material 451: First corner
452: Second corner 453: Third corner
454: Fourth corner 5, 5′: Conductive bonding material
50: Overlapping portion 50′: Central portion
501: First edge 501A: First edge first portion
501B: First edge second portion
501C: First edge third portion
501d: First edge first inclined portion
501e: First edge second inclined portion
502: Second edge 502A: Second edge first portion
502B: Second edge second portion
502C: Second edge third portion
502d: Second edge first inclined portion
502e: Second edge second inclined portion
503: Third edge 503A: Third edge first portion
503B: Third edge second portion
503C: Third edge third portion
503d: Third edge first inclined portion
503e: Third edge second inclined portion
504: Fourth edge 504A: Fourth edge first portion
504B: Fourth edge second portion
504C: Fourth edge third portion
504d: Fourth edge first inclined portion
504e: Fourth edge second inclined portion
51: First intermediate portion
52: Second intermediate portion
53: Third intermediate portion
54: Fourth intermediate portion
55: First extension 56: Second extension
57: Third extension 58: Fourth extension
61: First conductive member 611: First bonding portion
612: Second bonding portion 62: Second conductive member
621: First bonding portion 622: Second bonding portion
7: Sealing resin 71: Resin obverse surface
72: Resin reverse surface
731, 732, 733, 734: Resin side surface
D1: First distance D2: Second distance
D3: Third distance D4: Fourth distance
L1: First extension length L2: Second extension length
L3: Third extension length L4: Fourth extension length
Ld: Diagonal length x: First direction
y: Second direction z: Thickness direction
v: Third direction w: Fourth direction

1. A semiconductor device comprising:
a support member including an obverse surface facing one side in a thickness direction;
a semiconductor element including an element obverse surface and an element reverse surface that face away from each other in the thickness direction and a reverse surface electrode disposed on the element reverse surface; and
a conductive bonding material that conductively bonds the obverse surface of the support member and the reverse surface electrode to each other, wherein
the semiconductor element includes a first element side surface and a second element side surface that face a first side and a second side, respectively, in a first direction orthogonal to the thickness direction, and a third element side surface and a fourth element side surface that face a first side and a second side, respectively, in a second direction orthogonal to the thickness direction and the first direction,
as viewed in the thickness direction, the conductive bonding material includes a first edge located on the first side in the first direction relative to the first element side surface, a second edge located on the second side in the first direction relative to the second element side surface, a third edge located on the first side in the second direction relative to the third element side surface, and a fourth edge located on the second side in the second direction relative to the fourth element side surface,
a first distance between the first element side surface and the first edge in the first direction is greater at opposite ends than at a center of the first element side surface in the second direction,
a second distance between the second element side surface and the second edge in the first direction is greater at opposite ends than at a center of the second element side surface in the second direction,
a third distance between the third element side surface and the third edge in the second direction is greater at opposite ends than at a center of the third element side surface in the first direction, and
a fourth distance between the fourth element side surface and the fourth edge in the second direction is greater at opposite ends than at a center of the fourth element side surface in the first direction.

2. The semiconductor device according to claim 1, wherein
the first edge includes a first edge first portion, a first edge second portion and a first edge third portion, the first edge first portion extending in the second direction, the first edge second portion and the first edge third portion being connected to the first edge first portion, located outside the first edge first portion in the first direction, and located at an end closer to the third edge and at an end closer to the fourth edge, respectively, in the second direction,
the second edge includes a second edge first portion, a second edge second portion and a second edge third portion, the second edge first portion extending in the second direction, the second edge second portion and the second edge third portion being connected to the second edge first portion, located outside the second edge first portion in the first direction, and located at an end closer to the third edge and at an end closer to the fourth edge, respectively, in the second direction,
the third edge includes a third edge first portion, a third edge second portion and a third edge third portion, the third edge first portion extending in the first direction, the third edge second portion and the third edge third portion being connected to the third edge first portion, located outside the third edge first portion in the second direction, and located at an end closer to the first edge and at an end closer to the second edge, respectively, in the second direction, and
the fourth edge includes a fourth edge first portion, a fourth edge second portion and a fourth edge third portion, the fourth edge first portion extending in the first direction, the fourth edge second portion and the fourth edge third portion being connected to the fourth edge first portion, located outside the fourth edge first portion in the second direction, and located at an end closer to the first edge and at an end closer to the second edge, respectively, in the second direction.

3. The semiconductor device according to claim 2, wherein
the first edge second portion includes a first edge first inclined portion connected to the first edge first portion and extending in a third direction crossing the first direction and the second direction as viewed in the thickness direction,
the first edge third portion includes a first edge second inclined portion connected to the first edge first portion and extending in a fourth direction crossing the first direction and the second direction as viewed in the thickness direction,
the second edge second portion includes a second edge first inclined portion connected to the second edge first portion and extending in the fourth direction as viewed in the thickness direction,
the second edge third portion includes a second edge second inclined portion connected to the second edge first portion and extending in the third direction as viewed in the thickness direction,
the third edge second portion includes a third edge first inclined portion connected to the third edge first portion and extending in the third direction as viewed in the thickness direction,
the third edge third portion includes a third edge second inclined portion connected to the third edge first portion and extending in the fourth direction as viewed in the thickness direction,
the fourth edge second portion includes a fourth edge first inclined portion connected to the fourth edge first portion and extending in the fourth direction as viewed in the thickness direction, and
the fourth edge third portion includes a fourth edge second inclined portion connected to the fourth edge first portion and extending in the third direction as viewed in the thickness direction.

4. The semiconductor device according to claim 3, wherein
as viewed in the thickness direction, the conductive bonding material includes: a first intermediate portion located between the first element side surface and the first edge first portion, a second intermediate portion located between the second element side surface and the second edge first portion, a third intermediate portion located between the third element side surface and the third edge first portion, a fourth intermediate portion located between the fourth element side surface and the fourth edge first portion;
a first extension including the first edge first inclined portion and the third edge first inclined portion and extending outward in the third direction from a first corner that is a boundary between the first element side surface and the third element side surface;
a second extension including the first edge second inclined portion and the fourth edge first inclined portion and extending outward in the fourth direction from a second corner that is a boundary between the first element side surface and the fourth element side surface;
a third extension including the second edge first inclined portion and the third edge second inclined portion and extending outward in the fourth direction from a third corner that is a boundary between the second element side surface and the third element side surface; and
a fourth extension including the second edge second inclined portion and the fourth edge second inclined portion and extending outward in the third direction from a fourth corner that is a boundary between the second element side surface and the fourth element side surface.

5. The semiconductor device according to claim 4, wherein as viewed in the thickness direction, each of a first extension length from the first corner to an extremity of the first extension in the third direction, a second extension length from the second corner to an extremity of the second extension in the fourth direction, a third extension length from the third corner to an extremity of the third extension in the fourth direction, and a fourth extension length from the fourth corner to an extremity of the fourth extension in the third direction is 0.01 to 1 times a diagonal length from the first corner to the third corner of the semiconductor element.

6. The semiconductor device according to claim 4, wherein a thickness of each of the first extension, the second extension, the third extension and the fourth extension is greater than a thickness of the first intermediate portion, the second intermediate portion, the third intermediate portion and the fourth intermediate portion.

7. The semiconductor device according to claim 6, wherein the thickness of each of the first extension, the second extension, the third extension and the fourth extension is not greater than ⅔ of a thickness of the semiconductor element.

8. The semiconductor device according to claim 1, wherein the conductive bonding material contains silver.

9. The semiconductor device according to claim 1, wherein the conductive bonding material comprises a sintered metal.

10. The semiconductor device according to claim 1, wherein the support member is a first lead including the obverse surface of the support member and made of a metal plate.

11. The semiconductor device according to claim 10, wherein the obverse surface of the first lead includes a region overlapping with the conductive bonding material as viewed in the thickness direction, and the region is formed with a plating layer.

12. The semiconductor device according to claim 10, further comprising:
a second lead spaced apart from the first lead as viewed in the thickness direction and made of a metal plate; and
a first conductive member, wherein
the semiconductor element includes a first obverse surface electrode disposed on the element obverse surface, and
the first conductive member is connected to the first obverse surface electrode and the second lead.

13. The semiconductor device according to claim 12, further comprising: a third lead spaced apart from the first lead and the second lead as viewed in the thickness direction and made of a metal plate; and
a second conductive member, wherein
the semiconductor element includes a second obverse surface electrode disposed on the element obverse surface, and
the second conductive member is connected to the second obverse surface electrode and the third lead.

14. The semiconductor device according to claim 13, wherein the reverse surface electrode is a drain electrode, the first obverse surface electrode is a source electrode, and the second obverse surface electrode is a gate electrode.

15. A method for manufacturing a semiconductor device, the method comprising the steps of:
preparing a support member including an obverse surface facing one side in a thickness direction;
disposing a conductive bonding material on the obverse surface;
disposing a semiconductor element on the support member, the semiconductor element including an element obverse surface and an element reverse surface that face away from each other in the thickness direction and a reverse surface electrode disposed on the element reverse surface and being rectangular as viewed in the thickness direction, the semiconductor element being disposed such that the reverse surface electrode is on the conductive bonding material; and
heating the conductive bonding material to bond the obverse surface of the support member and the reverse surface electrode to each other with the conductive bonding material,
wherein disposing the conductive bonding material includes forming, in the conductive bonding material, extensions that extend from positions respectively corresponding to four corners of the semiconductor element toward an outside of the semiconductor element as viewed in the thickness direction.
